(19) United States
(12) Patent Application Publication
(10) Pub. No.: US 2024/0230767 A1
(43) Pub. Date: Jul. 11, 2024

(54) METHOD AND CONTROL DEVICE FOR DETERMINING AN ENERGY QUANTITY IN A BATTERY OR BATTERY CELL

(71) Applicant: Volkswagen Aktiengesellschaft, Wolfsburg (DE)

(72) Inventors: Marian Vlcek, Prague (CZ); Jiri Valtr, Prague (CZ); Adam Hrazdira, Prague (CZ); Stefan Aust, Braunschweig (DE)

(21) Appl. No.: 18/560,315

(22) PCT Filed: Mar. 10, 2022
(86) PCT No.: PCT/EP2022/056242

§ 371 Date: Feb. 12, 2024

(30) Foreign Application Priority Data
May 20, 2021 (DE) 102021205163.4

(51) Int. Cl. G01R 31/367; G01R 31/3835

(52) U.S. Cl. CPC G01R 31/367; G01R 31/3835

(57) ABSTRACT

Technologies and techniques for determining an energy quantity in a battery or battery cell, wherein an initial charge state and a final charge state is received. A load profile between the initial charge state and the final charge state is received, and intermediate charge states between the initial charge state and the final charge state and associated weighting factors are determined. Parameters of an equivalent circuit model of the battery or the battery cell are estimated for each of the determined intermediate charge states, and, proceeding from the load profile, the weighting factors and the parameters, an energy quantity of the battery or battery cell between the initial charge state and the final charge state is determined and is provided as an energy quantity signal. An associated control device for determining an energy quantity in a battery or battery cell is also disclosed.

### RELATED APPLICATIONS

The present application claims priority to International Patent Application No. PCT/EP2022/056242 to Vlcek et al., filed Mar. 10, 2022, titled “Method And Control Device For Determining An Energy Quantity In A Battery Or Battery Cell,” which claims priority to German Pat. App. No. DE 10 2021 205 163.4, filed May 20, 2021, to Vlcek et al., the contents of each being incorporated by reference in their entirety herein.

### TECHNICAL FIELD

The present disclosure relates to a method and to a control device for determining an amount of energy in a battery or a battery cell.

### BACKGROUND

Batteries, and li-ion batteries in particular, are becoming ever more important due to the increasing electrification of vehicles. A key characteristic variable is the amount of energy that is withdrawn from or added to the battery during the operation thereof. With the aid of the amount of energy, it is possible to determine a remaining driving range, an operating time, or an amount of energy required until the battery is fully charged. In addition, an amount of energy can be determined both in the charging direction and in the discharging direction. Moreover, an amount of energy can also be determined during intervals between states of charge (SOC) of the battery. Precisely determining amounts of energy is crucial for determining a (current) condition of the battery.

A recursive method for adaptive multi-parameter regression is known from U.S. Pat. No. 7,612,532 B2, which is enhanced with forgetting factors unique to each regressed parameter. Applications of this method can include lead acid batteries, nickel-metal hydride batteries, and lithium-ion batteries. A control method is presented, having an arbitrary number of model parameters, each having its own time-weighting factor. A method for determining optimal values for the time-weighting factors is included, to give greater effect to recently obtained data for the determination of a system's state. A methodology of weighted recursive least squares is employed, wherein the time weighting corresponds to the exponential-forgetting formalism. The derived result does not involve matrix inversion, and the method is iterative, that is, each parameter is regressed individually at every time step.

### SUMMARY

Aspects of the present disclosure are directed to a method and a control device for determining an amount of energy in a battery or a battery cell, in which the amount of energy can be reliably determined.

Some aspects of the present disclosure are described in the independent claims, provided below. Other advantageous embodiments are disclosed in the dependent claims.

In some examples, a method is disclosed for determining an amount of energy in a battery or a battery cell, wherein a starting state of charge is received; an ending state of charge is received; and a load profile between the starting state of charge and the ending state of charge is received. Intermediate states of charge between the starting state of charge and the ending state of charge and associated weighting factors are determined; parameters of an equivalent circuit model of the battery or the battery cell are estimated for each of the determined intermediate states of charge; and, proceeding from the load profile, the weighting factors and the parameters, an amount of energy of the battery or battery cell between the starting state of charge and the ending state of charge are determined and provided in the form of an energy amount signal.

In some examples, a control device is disclosed for determining an amount of energy in a battery or a battery cell, the control device being configured to receive a starting state of charge, receive an ending state of charge, and receive a load profile between the starting state of charge and the ending state of charge. The control device may determine intermediate states of charge between the starting state of charge and the ending state of charge and associated weighting factors, determine parameters of an equivalent circuit model of the battery or of the battery cell for each of the determined intermediate states of charge, and, proceeding from the load profile, the weighting factors and the parameters, to determine an amount of energy of the battery or battery cell between the starting state of charge and the ending state of charge and provide it in the form of an energy amount signal.

Further aspects of the control device will be apparent from the description of the embodiments provided below. Advantages of the control device are in each case the same as with the embodiments of the method.

### DESCRIPTION OF THE DRAWINGS

The present disclosure will be described in more detail hereafter based on preferred exemplary embodiments with reference to the figures. In the drawings:

FIG. 1 illustrates a schematic representation of one embodiment of the control device for determining an amount of energy in a battery or a battery cell, according to some aspects of the present disclosure;

FIG. 2 illustrates a schematic flow chart of a processing operation in the control device according to one embodiment of the method, according to some aspects of the present disclosure; and

FIG. 3 illustrates s a schematic representation of the equivalent circuit model, according to some aspects of the present disclosure.

### DETAILED DESCRIPTION

In some examples, aspects of the method and the control device allow the amount of energy to be better determined, and in particular to be better estimated. For this purpose, it is provided that parameters of an equivalent circuit model of the battery or of the battery cell are in each case estimated for intermediate states of charge within an interval between a starting state of charge and an ending state of charge. The parameters may be estimated as a function of the respective considered intermediate states of charge. Furthermore, a temperature or a temperature dependence is also taken into consideration during the estimation of the parameters. The parameters are thus dependent on the respective intermediate state of charge and the respective present temperature. The temperature can be sensed, for example, by means of a temperature sensor at the battery or battery cell or be provided in another manner, for example, estimated. Proceeding from a received load profile, the weighting factors and the estimated parameters, the amount of energy of the battery or of the battery cell between the starting state of charge and the ending state of charge is determined. The determined amount of energy is provided in the form of an energy amount signal. The energy amount signal can be analog or digital. The energy amount signal can, for example, be transmitted to a battery control system and/or a vehicle control system or a charging infrastructure.

One advantage of the method and of the control device is that, by taking state of charge-dependent, and in particular also temperature-dependent, parameters into consideration, it is possible to take losses that occur in the battery or the battery cell better into consideration. The amount of energy between the starting state of charge and the ending state of charge can thus be better determined.

The starting state of charge and the ending state of charge may be configured between a minimum state of charge and a maximum state of charge of the battery or of the battery cell. The starting state of charge and the ending state of charge may be received in the form of an analog or digital starting state of charge signal and an analog or digital ending state of charge signal, for example, from a battery control system and/or a vehicle control system. The starting state of charge and the ending state of charge can also be queried from a battery control system or a vehicle control system.

A load profile may denote a current during charging and/or during discharging between the starting state of charge and the ending state of charge. The load profile can be based both on detected sensor data (current measurement) and on predefined, for example simulated or estimated, data. In some examples, the load profile can be time-resolved.

In some examples, the parameters of the equivalent circuit model may have been empirically determined for different states of charge and temperatures of the battery. The determined parameters are then stored in a memory of the control device, and can be retrieved as needed, and optionally be provided in an interpolated manner, when the parameters are to be estimated for an intermediate state of charge. However, as an alternative or in addition, it is also possible to determine and/or to estimate the parameters by simulation.

The determined intermediate states of charge may form support points during a numerical integration carried out for determining the amount of energy. In some examples, the intermediate states of charge between the starting state of charge and the ending state of charge and the associated weighting factors are determined as specifications by a selected numerical integration method. In other words, the selected numerical integration method predefines the intermediate states of charge and the associated weighting factors as support points. As a result, an amount of energy within any arbitrary state of charge interval can be determined by means of integration over a voltage of the battery or of the battery cell. For example, open or closed Newton Cotes formulas can be selected as numerical integration methods, in which uniformly distributed support points are used. By means of Gauss-Legendre quadrature, it is also possible to use non-uniformly distributed support points. The method differs in the selection of the support points, but the remaining procedure is the same. In particular, the integral is always calculated as the weighted sum of the voltages at the support points. In principle, however, it is also possible to use other numerical integration methods.

Parts of the control device can, individually or together, be designed as a combination of hardware and software, for example as program code that is executed on a microcontroller or microprocessor. However, it may also be provided that parts, individually or together, are designed as an application-specific integrated circuit (ASIC) or a field-programmable gate array (FPGA).

The method and the control device may be used in a vehicle, such as a motor vehicle. A vehicle, however, can generally also be another land vehicle, a rail vehicle, a watercraft, an aircraft or a space craft, for example a drone or an air taxi. Generally, however, the method and the control device can also be employed with other mobile or stationary energy storage systems.

In general, an amount of energy can be calculated as follows:

$$E = {Q}_{Nominal} {\int }_{{SOC}_{Start}}^{{SOC}_{End}} UdSOC$$

Here, Q_{Nominal} is a capacity of the battery or of the battery cell having the unit Ah (ampere hours), SOC_{Start} is the starting state of charge, SOC_{End} is the ending state of charge (each being unitless, shown in percent or as a value between 0 and 1), U is the voltage of the battery or of the battery cell, and SOC is the state of charge of the battery or of the battery cell.

The integral is solved by means of a numerical integration method, for example by means of one of the open or closed Newton Cotes formulas:

$${\int }_{{SOC}_{Start}}^{{SOC}_{End}} UdSOC = ( {SOC}_{End} - {SOC}_{Start} ) {\sum }_{i} {w}_{i} U ( {SOC}_{i} )$$

Here, wᵢ is the weighting factor at the support point i corresponding to an intermediate state of charge SOCᵢ.

In one embodiment, the equivalent circuit model encompasses at least one open-circuit voltage, serving as the voltage source, a series resistor, and at least one RC circuit. In this way, the essential effects in the battery or the battery cell can be taken into consideration, and in particular a time-dependent behavior can be taken into consideration by means of the at least one RC circuit. In particular, the equivalent circuit model encompasses more than one RC circuit so that it is also possible to take several time-dependent processes within the battery or the battery cell into consideration.

In one embodiment, it is provided that, for the determination of the amount of energy for each intermediate state of charge, a total voltage of the battery or of the battery cell is determined at least from the open-circuit voltage, a series resistor voltage dropping across the series resistor, and an RC circuit voltage dropping across the at least one RC circuit. This enables a particularly efficient determination of the amount of energy. The RC circuits may be connected in series.

The voltage of the battery or of the battery cell then results as:

$$U = {U}_{OCV} + {U}_{R 0} + {\sum }_{n} {U}_{RC , n}$$

Here, U_{ocv} is the open-circuit voltage, U_{R0} is the series resistor voltage, and U_{RC.n} is the RC circuit voltage dropping across the n-th RC circuit. This applies to any intermediate state of charge SOCᵢ:

$$U ( {SOC}_{i} ) = {U}_{OCV} ( {SOC}_{i} ) + {U}_{R 0} ( {SOC}_{i} ) + {\sum }_{n} {U}_{RC , n} ( {SOC}_{i} )$$

The open-circuit voltage U_{ocv} is estimated as a parameter by the equivalent circuit model as a function of the intermediate state of charge SOCᵢ:

The following then results for the amount of energy E:

$$E = {Q}_{Nominal} ( {SOC}_{End} - {SOC}_{Start} ) {\sum }_{i} {w}_{i} U ( {SOC}_{i} )$$

In a refining embodiment, it is provided that the load profile is received in the form of a root mean square value of a current and an average value of the current, wherein the series resistor voltage dropping in each case across the series resistor for the intermediate states of charge is determined from the root mean square value of the current and the average value of the current. This allows the series resistor voltage to be reliably determined, in particular also for load profiles having a non-constant current profile.

The following results for the series resistor voltage U_{R0} dependent on the intermediate state of charge SOCᵢ:

$${U}_{R 0} ( {SOC}_{i} ) = {R}_{0} ( {SOC}_{i} ) \frac{{I}_{RMS}^{2}}{{I}_{Avg}}$$

Here, R₀ is the series resistance dependent on the intermediate state of charge SOCᵢ, I_{RMS} is the root mean square value of the current, and I_{Avg} is the average value of the current. R₀ is a parameter that is estimated by means of the equivalent circuit model for the respective intermediate state of charge. The average values can also be average values over few support points around the considered support point (for example, in the form of a moving average that takes a predefined number of support points into consideration).

In some examples, it is provided that, for the determination of the RC circuit voltage dropping across the at least one RC circuit, a time until the respective considered intermediate state of charge is reached is determined, proceeding from the starting state of charge, wherein the RC circuit voltage is determined proceeding from the determined time and a time constant of the at least one RC circuit. In this way, the RC circuit voltage of the at least one RC circuit can be better estimated, and consequently also the total voltage can be better determined.

The following results for the time ti until the respective considered intermediate state of charge SOCᵢ is reached:

$${t}_{i} = \frac{( {SOC}_{i} - {SOC}_{Start} ) {Q}_{Nominal}}{{I}_{Avg}}$$

The RC circuit voltage U_{RC.n} dependent on the intermediate state of charge SOC; then results as:

$${U}_{RC , n} ( {SOC}_{i} ) = {e}^{- \frac{{t}_{i}}{{τ}_{n}}} {U}_{RC , n} ( {SOC}_{Start} ) + ( 1 {-}^{- \frac{{t}_{i}}{{τ}_{n}}} ) {I}_{Avg} {R}_{RC , n} ( {SOC}_{i} )$$

Here, τₙ is the time constant for the n-th RC circuit. The RC circuit resistance R_{RC.n} is estimated as a parameter as a function of the intermediate state of charge SOCᵢ by means of the equivalent circuit model.

So as to reduce a required computing power, it may also be assumed in one embodiment that the RC circuits are saturated so that these can be substituted by constant resistances. Such an approach is possible, for example, when the load is constant (constant current in the load profile) and/or when the intervals between the starting state of charge and the ending state of charge are large.

Turning to FIG. 1, the figure shows a schematic representation of one embodiment of the control device 1 for determining an amount of energy 20 in a battery or a battery cell.

The control device 1 comprises a processing device 2 and a memory 3. The processing device 2 is, for example, a microprocessor or a microcontroller on which program code is being executed to carry out the method described in the present disclosure. However, it is also possible for hard-wired hardware components to be provided, which carry out part or all of the method. The control device 1 may be part of a battery control system.

A starting state of charge 10, an ending state of charge 11, and a load profile 12 are fed to the control device 1. Furthermore, it may be provided that a current temperature 13 of the battery or of the battery cell is fed to the control device 1. The current temperature of the battery or of the battery cell can, for example, be sensed by means of a temperature sensor 50 and/or can be estimated. The control device 1 can also form a shared device together with the temperature sensor 50. The starting state of charge 10, the ending state of charge 11, and the load profile 12 are, for example, queried from and/or provided by an energy management system (not shown) or a vehicle control system 51 of a vehicle (not shown). The starting state of charge 10, the ending state of charge 11, and the load profile 12 are received by the control unit 1 and processed by means of the processing device 2.

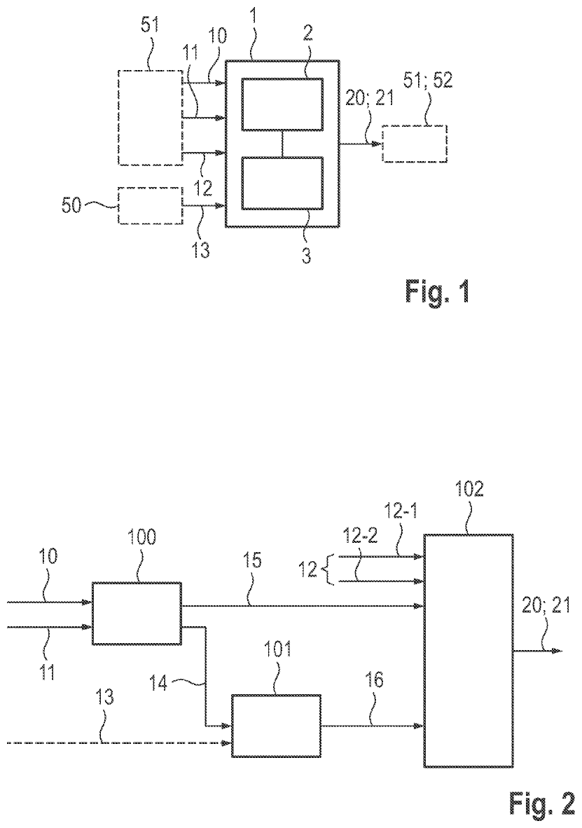

A processing operation in the control device 1 according to one embodiment of the method is schematically shown in FIG. 2 in the form of a flow chart, which illustrates a signal flow. The control device 1 is configured to determine intermediate states of charge 14, between the starting state of charge 11 and the ending state of charge 12, and associated weighting factors 15. This takes place in a module 100. For each of the determined intermediate states of charge 14, the control device 1, in a module 101, estimates parameters 16 of an equivalent circuit model of the battery or of the battery cell. This, in particular, also takes place taking the temperature 13 into consideration. The estimation is carried out, for example, proceeding from empirically determined parameters of the equivalent circuit model. It may be provided in the process that empirically determined parameters are interpolated. As an alternative or in addition, it may also be provided that the parameters are estimated proceeding from a simulation.

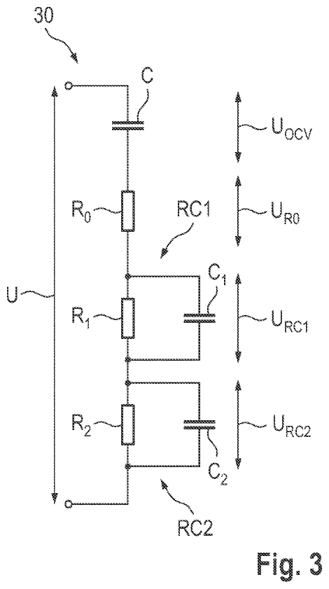

An exemplary equivalent circuit model 30 is schematically shown in FIG. 3. In the example, it is provided that the equivalent circuit model 30 encompasses at least an open-circuit voltage U_{ocv}, modeled in the form of a capacitance C, serving as the voltage source, a series resistor R₀, and two RC circuits RC1, RC2 including the resistors R1, R2 and the capacitors C1, C2. Generally, however, the equivalent circuit model 30 can also comprise more or fewer RC circuits RC1, RC2.

The parameters 16 (FIG. 2) that are estimated, as a function of a particular intermediate state of charge 14, are in particular the open-circuit voltage U_{ocv} (FIG. 3), the series resistance R₀ (FIG. 3), a resistance R1, R2 of the RC circuits RC1, RC2 (FIG. 3), and time constants of the RC circuits RC1, RC2. Furthermore, a voltage at the RC circuits RC1, RC2 is also estimated for the starting state of charge 10.

Proceeding from the load profile 12 (FIG. 2), which is, in particular, provided in the form of an average value 12-1 of the current and in the form of a root mean square value 12-2 of the current, the weighting factors 15, and the parameters 16, an amount of energy 20 of the battery or of the battery cell between the starting state of charge 10 and the ending state of charge 11 is determined in a module 102. The determined amount of energy 20 is provided in the form of an energy amount signal 21.

For determining the amount of energy, it is in particular provided that a total voltage U (FIG. 3) of the battery or of the battery cell is determined for each intermediate state of charge 14 at least from the open-circuit voltage U_{ocv}, a series resistor voltage U_{R0} dropping across the series resistor R₀, and an RC circuit voltage U_{RC1}, U_{RC2} dropping across the RC circuits RC1, RC2.

Here, it is, in particular, provided that the series resistor voltage U_{R0} dropping in each case across the series resistor R₀ for the intermediate states of charge 14 is determined from the root mean square value 12-2 (FIG. 2) of the current and the average value 12-1 (FIG. 2) of the current.

Furthermore, it is in particular provided that, for the determination of the RC circuit voltage U_{RC1}, U_{RC2} dropping across the at least one RC circuit RC1, RC2 (FIG. 3), a time until the respective considered intermediate state of charge 14 is reached is determined, proceeding from the starting state of charge 10, wherein the RC circuit voltage U_{RC1}, U_{RC2} is determined proceeding from the determined time and a time constant of the at least one RC circuit RC1, RC2.

The resulting total voltage U of the battery or of the battery cell is then numerically integrated over the interval between the starting state of charge 10 and the ending state of charge 11 to obtain the amount of energy 20. This can be carried out, for example, by means of open or closed Newton Cotes formulas. In principle, however, it is also possible to use other numerical integration methods. The energy amount signal 21, which encodes the value of the amount of energy 20 in suitable form, is then generated from the resultant amount of energy 20. The energy amount signal 21 can, for example, be fed to a battery control system 52 or the vehicle control system 51.

The method and the control device described herein enable an improved determination of amounts of energy in batteries or battery cells. The method and the control device can advantageously be used at different temperatures and at state of charge intervals of varying lengths. Furthermore, it is also possible to take non-constant load profiles into consideration so that it is possible to take losses that occur better into consideration. In addition, various charging histories can be taken into consideration since always a current state of charge of the battery is being considered.

### LIST OF REFERENCE NUMERALS

1 control device
2 processing device
3 memory
10 starting state of charge
11 ending state of charge
12 load profile
12-1 average value of the current
12-2 root mean square value of the current
13 temperature
14 intermediate state of charge
15 weighting factor
16 parameter
20 amount of energy
21 energy amount signal
30 equivalent circuit model
50 temperature sensor
51 vehicle control system
51 battery control system
100-102 modules
Cx capacitor
C capacitance (open-circuit voltage)
RCx RC circuit
Rx resistance
U total voltage
U_{oce} open-circuit voltage
R₀ series resistor
U_{R0} series resistor voltage
U_{RCx} RC circuit voltage

1-10. (canceled)

11. A method for controlling a device based on determining an amount of energy in a battery or a battery cell, comprising:
receiving a starting state of charge;
receiving an ending state of charge;
receiving a load profile between the starting state of charge and the ending state of charge;
determining intermediate states of charge between the starting state of charge and the ending state of charge and associated weighting factors;
estimating parameters of an equivalent circuit model of the battery or the battery cell being estimated for each of the determined intermediate states of charge;
determining an amount of energy of the battery or battery cell between the starting state of charge and the ending state of charge, based on the load profile, the weighting factors and the estimated parameters; and
generating a control signal based on the determined amount of energy.

12. The method according to claim 11, wherein estimating parameters of an equivalent circuit model comprises designating at least one open-circuit voltage as a voltage source comprising a series resistor, and at least one RC circuit.

13. The method according to claim 12, wherein determining an amount of energy comprises determining an amount of energy for each intermediate state of charge, and determining a total voltage of the battery or of the battery cell from the open-circuit voltage, a series resistor voltage dropping across the series resistor, and an RC circuit voltage dropping across the at least one RC circuit.

14. The method according to claim 13, wherein receiving the load profile comprises receiving a root mean square value of a current and an average value of the current.

15. The method according to claim 14, further comprising determining the series resistor voltage being dropped across the series resistor for the intermediate states of charge from the root mean square value of the current and the average value of the current.

16. The method according to claim 13, wherein determining the RC circuit voltage dropping across the at least one RC circuit comprises determining a time until a respective considered intermediate state of charge is reached.

17. The method according to claim 16, wherein, proceeding from a starting state of charge, the RC circuit voltage is determined proceeding from a determined time and a time constant of the at least one RC circuit.

18. A control device for controlling a device based on determining an amount of energy in a battery or a battery cell, comprising:
a memory; and
a processing device, operatively coupled to the memory, the processing device and memory being configured to
receive a starting state of charge;
receive an ending state of charge;
receive a load profile between the starting state of charge and the ending state of charge;
determine intermediate states of charge between the starting state of charge and the ending state of charge and associated weighting factors;
estimate parameters of an equivalent circuit model of the battery or the battery cell being estimated for each of the determined intermediate states of charge;
determine an amount of energy of the battery or battery cell between the starting state of charge and the ending state of charge, based on the load profile, the weighting factors and the estimated parameters; and
generate a control signal based on the determined amount of energy.

19. The control device according to claim 18, wherein the processing device and memory are configured to estimate parameters of an equivalent circuit model by designating at least one open-circuit voltage as a voltage source comprising a series resistor, and at least one RC circuit.

20. The control device according to claim 19, wherein the processing device and memory are configured to determine an amount of energy by determining an amount of energy for each intermediate state of charge, and determining a total voltage of the battery or of the battery cell from the open-circuit voltage, a series resistor voltage dropping across the series resistor, and an RC circuit voltage dropping across the at least one RC circuit.

21. The control device according to claim 20, wherein the processing device and memory are configured to receive the load profile by receiving a root mean square value of a current and an average value of the current.

22. The control device according to claim 21, wherein the processing device and memory are configured to determine the series resistor voltage being dropped across the series resistor for the intermediate states of charge from the root mean square value of the current and the average value of the current.

23. The control device according to claim 20, wherein the processing device and memory are configured to determine the RC circuit voltage dropping across the at least one RC circuit comprises determining a time until a respective considered intermediate state of charge is reached.

24. The control device according to claim 23, wherein, proceeding from a starting state of charge, the RC circuit voltage is determined proceeding from a determined time and a time constant of the at least one RC circuit.

25. A non-transitory computer-readable medium having stored therein instructions executable by one or more processors for controlling a device based on determining an amount of energy in a battery or a battery cell, the instructions being configured to:
receive a starting state of charge;
receive an ending state of charge;
receive a load profile between the starting state of charge and the ending state of charge;
determine intermediate states of charge between the starting state of charge and the ending state of charge and associated weighting factors;
estimate parameters of an equivalent circuit model of the battery or the battery cell being estimated for each of the determined intermediate states of charge;
determine an amount of energy of the battery or battery cell between the starting state of charge and the ending state of charge, based on the load profile, the weighting factors and the estimated parameters; and
generate a control signal based on the determined amount of energy.

26. The non-transitory computer-readable medium of claim 25, wherein the instructions are configured to estimate parameters of an equivalent circuit model by designating at least one open-circuit voltage as a voltage source comprising a series resistor, and at least one RC circuit.

27. The non-transitory computer-readable medium of claim 26, wherein the instructions are configured to determine an amount of energy bt determining an amount of energy for each intermediate state of charge, and determining a total voltage of the battery or of the battery cell from the open-circuit voltage, a series resistor voltage dropping across the series resistor, and an RC circuit voltage dropping across the at least one RC circuit.

28. The non-transitory computer-readable medium of claim 27, wherein the instructions are configured to receive the load profile by receiving a root mean square value of a current and an average value of the current.

29. The non-transitory computer-readable medium of claim 28, wherein the instructions are configured to determine the series resistor voltage being dropped across the series resistor for the intermediate states of charge from the root mean square value of the current and the average value of the current.

30. The method according to claim 28, wherein the instructions are configured to
determine the series resistor voltage being dropped across the series resistor for the intermediate states of charge from the root mean square value of the current and the average value of the current; and
determine the RC circuit voltage dropping across the at least one RC circuit by determining a time until a respective considered intermediate state of charge is reached.
